(19) United States
(12) Patent Application Publication
(10) Pub. No.: US 2011/0073982 A1
(43) Pub. Date: Mar. 31, 2011

(54) Inspection system using back side illuminated linear sensor

(76) Inventors: J. Joseph Armstrong, Milpitas, CA (US); Yung-Ho Chuang, Cupertino, CA (US); David L. Brown, Sunnyvale, CA (US)

(21) Appl. No.: 11/805,907

(22) Filed: May 25, 2007

(51) Int. Cl. H01L 31/00; G01N 21/00

(52) U.S. Cl. 257/460; 356/237.5; 257/E31.001

(57) ABSTRACT

An improved inspection system using back-side illuminated linear sensing for propagating charge through a sensor is provided. Focusing optics may be used with a back side illuminated linear sensor to inspect specimens, the back side illuminated linear sensor operating to advance an accumulated charge from one side of each pixel to the other side. The design comprises controlling voltage profiles across pixel gates from one side to the other side in order to advance charge between to a charge accumulation region. Controlling voltage profiles comprises attaching a continuous polysilicon gate across each pixel within a back side illuminated linear sensor array. Polysilicon gates and voltages applied thereto enable efficient electron advancement using a controlled voltage profile.

### BACKGROUND OF THE INVENTION

1. Field of the Invention

The present invention relates generally to the field of optical imaging and more specifically to optical systems for microscopic imaging, inspection and lithography applications.

2. Description of the Related Art

Many optical systems and electronic systems have an ability to inspect or image features on the surface of a specimen to determine defects. Specimens may include semiconductor wafers or photomasks and partially fabricated integrated circuits. Defects on such specimens may be relatively small in size and can take the form of imperfections randomly localized on the specimen surface, such as particles, scratches, process variations, repeating pattern defects, and so forth. Such defects are typically seven or more orders of magnitude smaller than the wafer itself.

Techniques and devices for inspecting specimens for these microscopic defects are generally available in the art and are embodied in various commercially available products, including those available from KLA-Tencor Corporation of San Jose, Calif.

The aim of virtually any type of inspection system or technique is to rapidly and efficiently detect defects. With smaller and smaller features on specimen surfaces and the use of new materials and new manufacturing processes, detection of new and finer defects is required. It is also preferable to rapidly inspect a specimen surface in as short an amount of time as possible, from loading the specimen to removing it from the inspection position and characterizing the defects. Such speed requirements in the presence of smaller features mandate continuous improvements in the available systems and techniques to accurately and adequately find specimen problems.

These types of optical inspection systems may employ sophisticated sensors, including but not limited to linear sensors. Linear sensors are generally a plurality of sensing elements oriented along a line positioned to receive a line of data, such as a line of illumination from a specimen. Linear sensors can provide increased throughput in specimen inspection systems and photomask systems over other types of sensors in various illumination modes, particularly in darkfield or directional darkfield inspection modes.

Currently available linear sensors employed in darkfield inspection operate at very high speeds. In such linear sensors, the illumination is incident on the active sensor elements as well as the layer and gate structures that determine the electrical performance of the device. Such a configuration, known as front-illuminated, can be problematic because the resulting surface cannot generally be fully optimized for both optical performance, including high, stable quantum efficiency, and electrical performance, such as high speed and efficient, stable charge transport. Such devices can also be susceptible to long-term ultra-violet and deep ultra-violet light damage, particularly in high sustained data-rate applications (heavy use conditions). High sustained data rate applications usually expose the sensor to much higher performance requirements than typical scientific applications for ultraviolet (UV) and deep ultraviolet (DUV) compatible sensors such as spectroscopy. Various design techniques and performance compromises have been attempted but have not solved all of the issues.

The pixel size or aspect ratio can limit the operating speed of a linear sensor. In a device with a large pixel length-to-width ratio and uniform potential, the time required to drain the charge from the pixel can increase with pixel length according to the equation:

Q(t)=(8/π²)*Q₀*Exp(−(π²/4)*Dn*t/L²), (1)

where Q is the signal charge in the pixel, Q₀ is the initial amount of charge at time equal to 0, Dn is the diffusion constant related to the material charge mobility, and L is the pixel length. This equation may be found in “Solid-State Imaging with Charge-Coupled Devices,” Albert J. P. Theuwissen, 1995, ISBN 0-7923-3456-6, p. 28.

As a result, longer pixels, or longer aspect ratio pixels, can require much longer times to collect all signal charge due to the dependence on the length squared. This can result in a phenomenon called image lag, which reduces the sensor performance in high-speed inspection applications. The estimate uses worst-case assumptions but is valid for small signals when very high sensitivity is needed or for large pixels that are not used at full capacity. In DUV applications, where the front-illuminated pixel cannot be covered with a gate, it is difficult to provide a potential variation within the pixel over a large region.

Darkfield inspection typically produces a dark background with bright foreground features resulting from scattered light, such as laser light energy. Features inspected using darkfield techniques can be 1000 times more intense than the background, while some defects of interest may have a brightness that is very close to the background. The bright signal from certain features can saturate and spill over into adjacent pixels, an effect known as blooming. Lack of effective anti-blooming capability can make linear sensors unsuitable for high-speed darkfield ultra-violet darkfield inspection applications.

It would be beneficial to provide a linear sensor for use in conjunction with a specimen inspection device, including semiconductor wafer or photomask and partially fabricated integrated circuit inspections, that overcome the foregoing drawbacks present in previously known sensing designs. Further, it would be beneficial to provide a sensing arrangement and overall optical inspection system design having improved functionality over devices exhibiting the negative aspects described herein.

### SUMMARY OF THE INVENTION

According to a first aspect of the present design, there is provided a specimen inspection device, comprising optics configured to focus a beam of radiation into a focused beam at an oblique incidence angle to a focused line on a surface of a specimen, and a back-side illuminated linear sensor comprising an imaging region formed by a linearly aligned plurality of pixels. All pixels are covered by a single polysilicon gate layer, an oxide layer formed adjacent to the polysilicon layer, a n-type material layer adjacent to said oxide layer, and a p-type material formed adjacent to said n-type layer.

Applying two constant voltages along the entire opposite edges of the gate region causes electrons to advance within each pixel toward an accumulation region. The advancing is enhanced by a nearly uniform and continuous electric field from the applied gate voltages. The conductivity of the gate can be chosen to maintain electric field uniformity while minimizing the current required and thus keeping power dissipation to manageable levels. Polysilicon gates may be doped or overcoated with conducting materials to achieve the required conductivity.

According to a second aspect of the present design, there is provided a method of inspecting specimens using a sensor comprising an array of linearly aligned pixels. The method comprises orienting each pixel and configuring the sensing device such that light energy reflected from a specimen is received at a back-side of said device and is collected in a pixel potential well near the front side of the device. Applying a plurality of constant voltages in stair-step fashion across regions of each pixel then causes electrons to advance or drift within each pixel toward an accumulation. The advancing is enhanced by transverse electric fields from the applied gate voltages.

These and other advantages of the present invention will become apparent to those skilled in the art from the following detailed description of the invention and the accompanying drawings.

### DESCRIPTION OF THE DRAWINGS

The present invention is illustrated by way of example, and not by way of limitation, in the figures of the accompanying drawings in which:

FIG. 1 illustrates a section of a typical high-speed linear sensor with long aspect ratio pixels;

FIG. 2 illustrates a pixel cross-section typically employed in a front side illuminated linear sensor;

FIG. 3 illustrates an inspection system and optical path using a linear sensor;

FIG. 4 illustrates a cross section of a back side illuminated linear sensor pixel;

FIG. 5 illustrates a top view of a pixel for a back side illuminated linear sensor in accordance with the present design;

FIG. 6 shows a single continuous polysilicon gate over the exposure region for a back side illuminated linear sensor in accordance with the present design.

### DETAILED DESCRIPTION OF THE INVENTION

According to the present invention, there is provided an inspection system comprising a back side illuminated linear sensing arrangement that employs one or more gates over the exposure region to facilitate control of the voltage profile across the exposed area. The design orients each pixel and configures the sensing device such that light energy reflected from a specimen is received at a back-side of the sensing device and is collected in a pixel potential well near the front side of the device. Applying a plurality of constant voltages in stair-step fashion across regions of each pixel then causes electrons to advance or drift within each pixel toward an accumulation region or zone. Advancing is enhanced by transverse electric fields from the applied gate voltages.

The design is particularly applicable to inspection and metrology systems. The implementation is either a single gate implementation or multiple gate implementation producing in either case a continuous voltage ramp. The present design employs a back thinned and linear array architecture particularly suited to inspection, such as semiconductor inspection, and metrology applications. Anti-blooming is provided in the pixel array, and in one orientation a plurality of pixels, and in certain cases all pixels, are linearly aligned. A sensor with long aspect ratio pixels such as those provided here can achieve high speed inspection of specimens such as semiconductor wafers.

The back-side illuminated linear sensor comprises an imaging region formed by a linearly aligned plurality of pixels. All pixels are covered by a single polysilicon gate layer, an oxide layer formed adjacent to the polysilicon layer, a n-type material layer adjacent to the oxide layer, and a p-type material formed adjacent to the n-type layer. Applying two constant voltages along the entire opposite edges of the gate region causes electrons to advance within each pixel toward an accumulation region. The conductivity of the gate can be chosen to maintain electric field uniformity while minimizing the current required and thus keeping power dissipation to manageable levels. Polysilicon gates may be doped or overcoated with conducting materials to achieve the required conductivity.

The present design may offer improvements over previously known linear sensor designs used in scanning or inspecting applications.

Various inspection modes may be employed in accordance with the present design, depending on the application and environment, including but not limited to darkfield inspection, directional darkfield inspection, and other modes wherein a linear sensor provides favorable results.

### Front Side Illuminated Linear Sensors

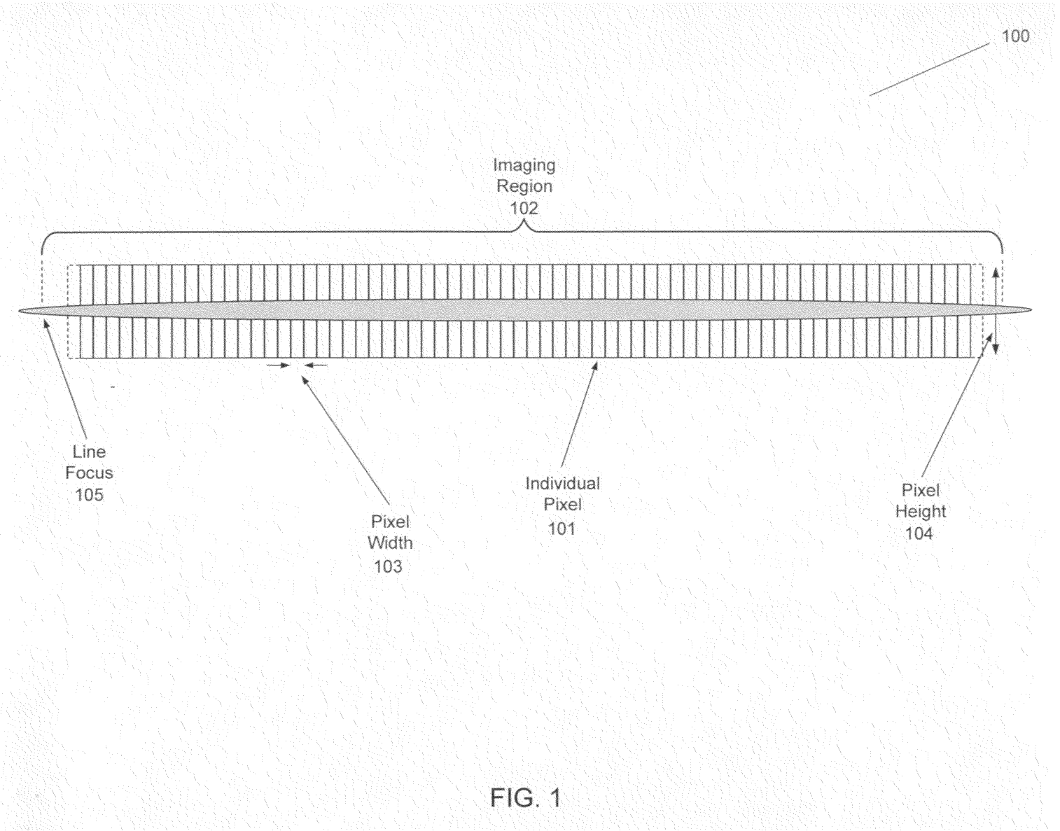

FIG. 1 illustrates a section of a currently available front side illuminated linear sensor 100. From FIG. 1, a one-dimensional array of individual pixels 101 of arbitrary length forms the imaging region 102 for linear sensor 100. Each pixel 101 in the one-dimensional array features a pixel width 103 and pixel height 104. A current state-of-the-art linear sensor can be configured such that the pixel height 104 is much larger than the pixel width 103. This pixel configuration mitigates the need to precisely position the line of focus 105 on linear sensor 100.

Many different inspection modes exist for specimen inspection, including inspection of partially fabricated integrated circuits. Linear sensor 100 is appropriate for use in high-speed inspection when used in conjunction with a darkfield inspection mode, a directional darkfield inspection mode, and other inspection modes. The directional darkfield inspection mode can be implemented using reflection of light energy for the purpose of inspecting specimens. In a typical arrangement, a laser beam or other illumination source illuminates the specimen surface (e.g. semiconductor wafer). The specimen surface reflects light onto the linear sensor 100, and at the points where light strikes the one-dimensional array of individual pixels 101 comprising linear sensor 100 the sensor may produce photoelectrons.

Linear sensors for darkfield inspection operate at high speed and have high dynamic range. High speed operation enables inspection of as many specimens as possible with reduced inspection costs. This is especially important as feature sizes decrease and higher sensitivity inspection is required. For high sensitivity darkfield inspection, a linear sensor with high dynamic rage is also required.

A darkfield inspection mode is primarily used to detect scattering from edges, small particles, and irregular surfaces. For example, smooth flat areas scatter very little light resulting in a dark image. Any surface features, particles, or objects protruding above the flat area scatter light and produce a bright area or region. Darkfield inspection modes provide a large signal for small features that have a tendency to scatter the light energy received. This large signal allows larger sensor pixels 101 to be used for a given feature size, permitting faster specimen inspections.

Darkfield inspection may be used with Fourier filtering. Filtering specimens that present repeating patterns using Fourier techniques can minimize the errors or false defects associated with repeating patterns and can enhance the defect signal to noise ratio.

A directional darkfield inspection mode can be employed in various configurations. The configuration employed typically depends on the particular type of defect encountered or anticipated to be found. The most common configuration, sometimes referred to as laser directional darkfield, uses one or more lasers to illuminate the specimen at high angles of incidence. In one configuration, the lasers are focused on a single spot imaged onto single element detectors. However, use of this configuration is problematic for inspecting specimens because it is very time consuming and thus increases the cost of each inspection. Furthermore, single spot inspection is problematic because it is difficult to scale to higher speeds. One method to increase the inspection speed is to focus the laser into a line on the sample and image this line onto a linear array of sensors. This method of using the line focus 105 on linear sensor 100 effectively enables the directional darkfield inspection mode to operate over multiple sensing elements in parallel.

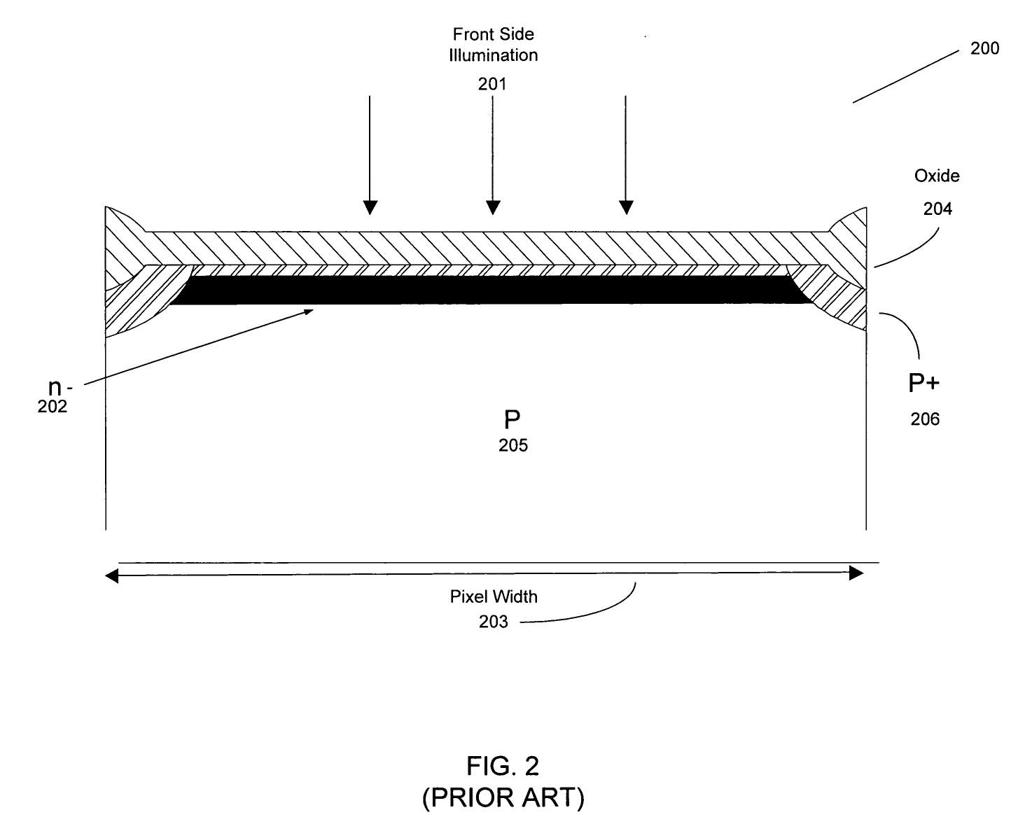

FIG. 2 illustrates a pixel cross section typically employed in a front side illuminated linear sensor 200. In this illustration, the pixel has pixel width 203. Light energy is received from the front side illumination source 201. The photoelectrons (not shown in FIG. 2) tend to be absorbed near the surface in the n− layer 202 for UV illumination. When front side illumination 201 is applied to the array of pixels forming front side illuminated linear sensor 200, charge in the form of electrons moves into the potential well formed by the P type material 205 to the n− type material 202. The P+ type material 206 results in a potential barrier which prevents charge from moving to adjacent pixels. If any of this region is covered with a polysilicon or other conductive gate over the oxide, then near-visible and UV illumination will be strongly absorbed by the gate and will not reach the collection well of the pixel.

Front side illuminated sensors are constructed using a relatively thick oxide and nitride surface 204. These surfaces can be problematic because the resulting surface is reflective and the quantum efficiency is relatively low and can be difficult to improve by adding an antireflection coating. Front side illuminated linear sensors are also susceptible to ultra-violet and deep ultra-violet light damage. Typical front side illuminated linear sensors do not exhibit optimum quantum efficiency and are not resistant to damage. Further, the gates on the front side illuminated linear sensor are typically made of materials that absorb ultra-violet and darkfield ultra-violet light.

The device sensitivity may be modified by allowing the gate to be opened, such as by punching holes in the oxide gate. This architectural change can provide some improvement in the quantum efficiency in the ultra-violet range, however the quantum efficiency is still limited because the open area must be relatively small, such as a very narrow diameter hole in the oxide layer. Other attempts to enhance performance can have negative performance aspects associated therewith. For example, increasing the area on a front side illuminated linear sensor degrades performance. Furthermore, the structure required for front side illuminated linear sensors can limit the ultra-violet light stability.

Linear sensors 200 are susceptible to blooming. Blooming occurs when a bright illumination source is used that causes photoelectrons to saturate the pixel and ‘spill-over’ into the adjacent pixels or charge transfer structures. After adding design constraints needed for DUV light sensitivity and high speed optimization, linear sensors used for inspection applications have limited flexibility to implement anti-blooming structures. For these reasons it can be difficult if not impossible to include anti-blooming capabilities in such linear sensors.

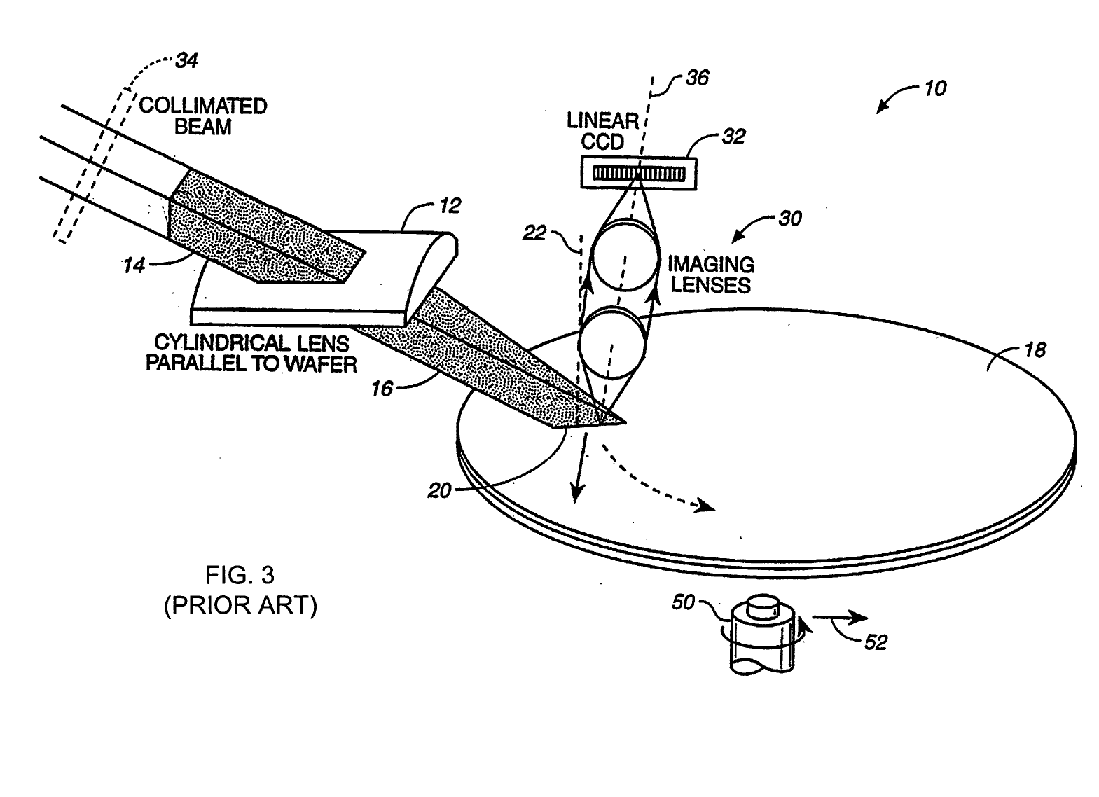

FIG. 3 illustrates a previous semiconductor wafer inspection system using a single imaging relay and a linear CCD sensor 32. System 10 includes a cylindrical objective such as a cylindrical lens 12 for focusing a collimated light beam 14 to a focused beam 16 for illuminating, on surface 18 to be inspected, an area in the shape of a line 20. Beam 14 and therefore also focused beam 16 are directed at an oblique angle of incidence to the surface 18. Line 20 is substantially in the incidence plane or plane of incidence of focused beam 16. The incidence plane of beam 16 is defined by the common plane containing beam 16 and a normal direction such as direction 22 to surface 18 and passing through beam 16. In order for the illuminated line 20 to be in the focal plane of lens 12, cylindrical lens 12 is oriented so that its principal plane is substantially parallel to surface 18. Image of the line is focused by an imaging subsystem 30 to an array of detectors, such as a linear array of CCDs 32. The linear array 32 may be parallel to line 20.

The imaging subsystem 30 in FIG. 3 has an optical axis 36 substantially normal to line 20 so that the center portion of the linear CCD array 32 is in a plane substantially normal to the incidence plane of beam 16. The optical axis 36 may be oriented in any direction within such plane, including a position directly above the line 20. In such event, array 32 would also be directly above line 20. The imaging subsystem 30 projects an image of a portion of the line 20 onto a corresponding detector in the CCD array 32 so that each detector in the array detects light from a corresponding portion of the line 20. The length of the line 20 is limited only by the size of the collimated input beam 14 and the physical aperture of lens or lens combination 12. In order to control the length of line 20, an optional expander 34 shown in dotted lines may be used for controlling the diameter of beam 14 so as to control the length of line 20.

In FIG. 3, both the illumination and collection portions of system 10 are stationary and surface 18 is rotated about a spindle 50 which is also moved along direction 52 so that line 20 scans surface 18 in a spiral path to cover the entire surface.

In an arrangement such as that shown in FIG. 3, illumination is focused into a line pattern near the wafer surface 18. The scattered light from the wafer surface 18 is collected by one or more optical relays and imaged onto one or more linear sensors positioned similar to sensor 32 in FIG. 3. Each relay and linear sensor comprises a detector channel. In the more general case one relay may also be used with multiple linear sensors.

### Back Side Illuminated Linear Sensor

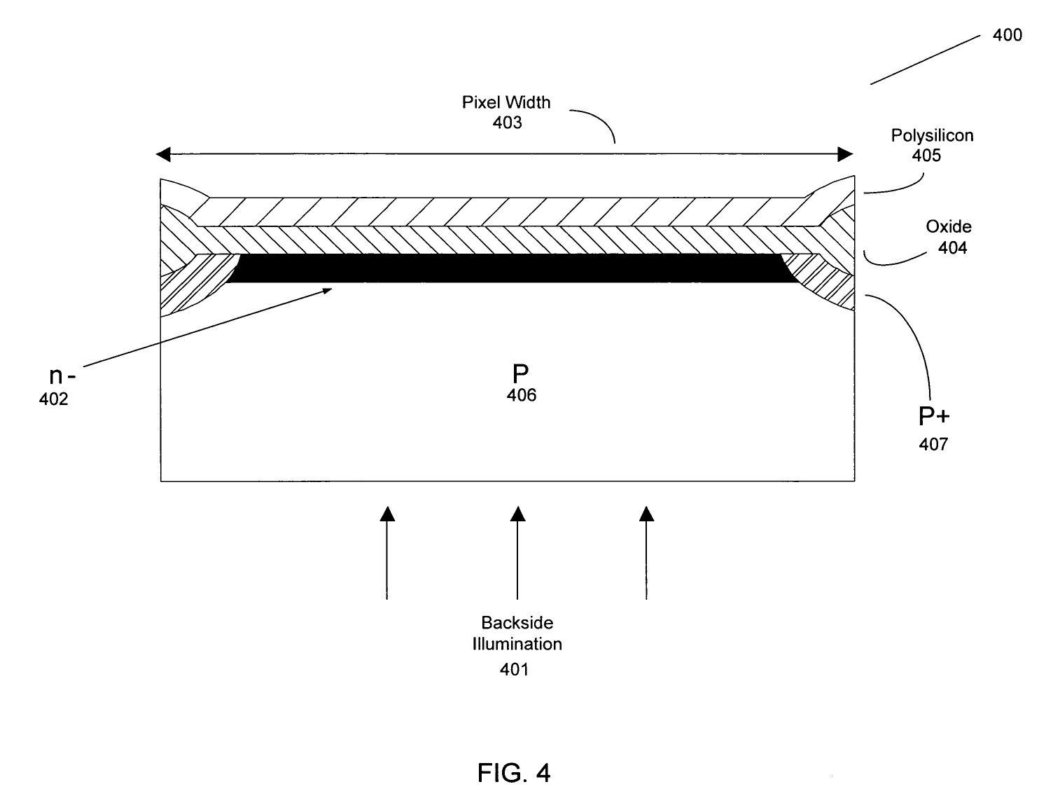

FIG. 4 illustrates a pixel cross section of a back side illuminated linear sensor 400 in accordance with the present design. In this illustration, the pixel features a pixel width 403. Light comes in from a source as back side illumination 401 and the photoelectrons (not shown in FIG. 4) may accumulate in the pixel's n− region 402. The front side of these sensors is constructed with an oxide surface 404, similar to the front side illumination linear sensor shown in FIG. 2 and incorporates one or more polysilicon gates 405 for each pixel. This structure enables application of a voltage potential to the polysilicon gate. This applied voltage potential may facilitate the charge, i.e. electrons, to move in the desired direction from the P type material 406 to the n− type material 402. Performance and other attributes of the P, n−, and P+ materials beyond those disclosed are generally known to those skilled in the art but are not particularly pertinent to the discussion here and are omitted for brevity.

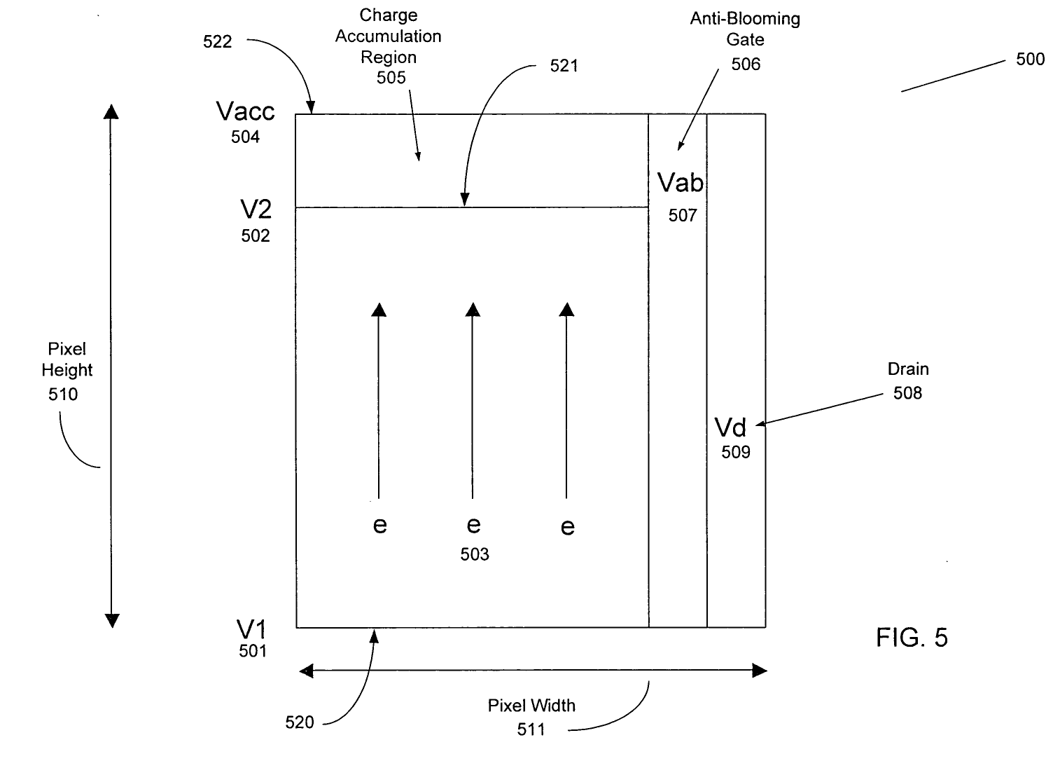

FIG. 5 illustrates a top view of a pixel for a back side illuminated linear sensor 500 in accordance with the present design. In this illustration, the pixel has pixel height 510 and a pixel width 511. In this arrangement the system applies a voltage potential V1 at 501 to a polysilicon gate (not shown in FIG. 5) that is less positive than the applied voltage potential V2 at 502. In general, the line of the pixel adjacent to V1 in FIG. 5 has V1 applied thereto, namely along line 520, while voltage V2 is applied along line 521. This voltage difference tends to cause electrons in region 503 to move toward the greater voltage potential V2 at line 521. In addition, the voltage potential V2 at line 521 is less positive than the voltage potential Vacc at line 522. Similarly, the voltage difference between these two regions may cause electrons to move toward the charge accumulation region 505. In the present design the optimization and layout of the front-side gates and dielectric structures is virtually independent of key optical parameters such a DUV quantum efficiency and stability.

Another embodiment of the present design may include an optional anti-blooming gate 506 and drain 508. The anti-blooming gate 506 prevents saturation and spillover into adjacent pixels that may result from applying a bright signal. The gate voltage potential Vab at 507 may be set at a value sufficient that the excess electrons in area 503 that would otherwise spill over into the next or adjacent pixels instead accumulate in drain 509. The drain potential Vd should be set sufficiently more positive than V2 502 so that charge moves across the Anti-blooming gate 507 and into drain 509.

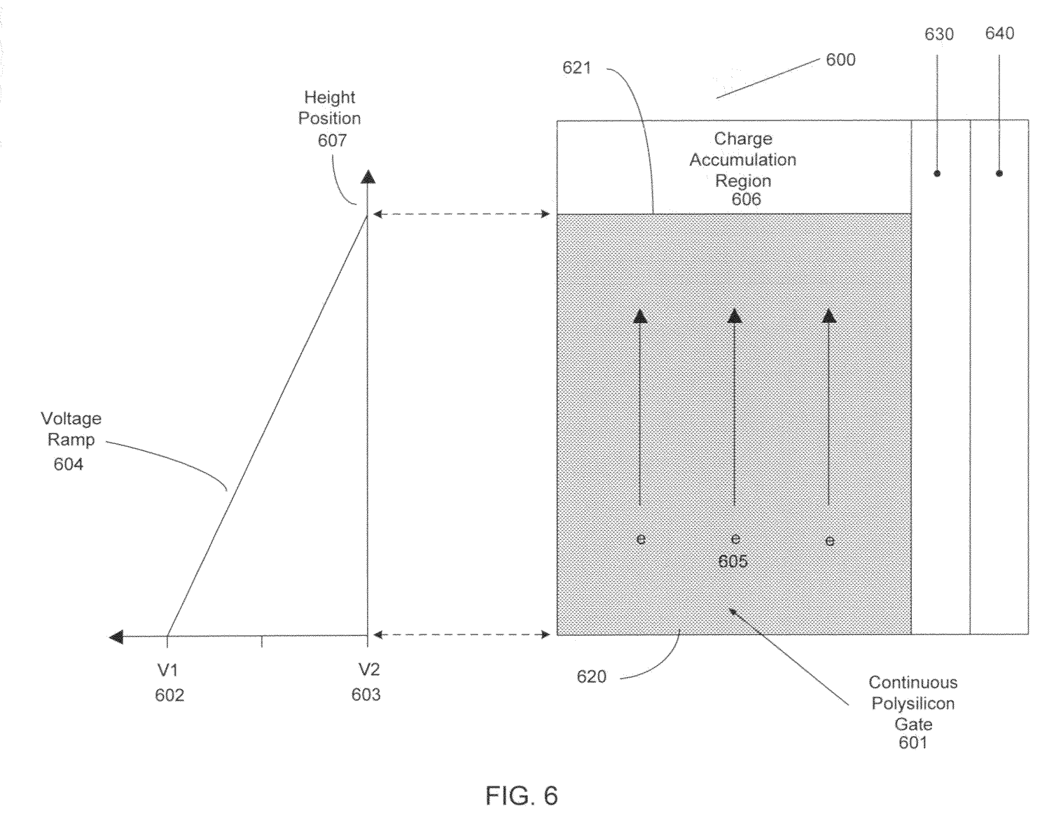

FIG. 6 illustrates a top view of a pixel for a back side illuminated linear sensor 600 that may incorporate a single continuous polysilicon gate 601 over the entire pixel exposure region. In this arrangement, a voltage potential V1 at 602 may be applied to the single continuous polysilicon gate 601 at one side or region of each pixel in the array. The system may apply voltage potential V2 at line 621, in the accompanying graph at point 603. Voltage V1 may be applied at line 620 in the single continuous polysilicon gate 601. In this arrangement, the present design may produce a continuous voltage ramp 604 from one side of the pixel to the other side. This allows the gate structures to cover the front-side pixels entirely without impacting the optical properties of the device.

While the present design is discussed with voltage being applied to a “line,” it is to be understood that the pixels and arrays described herein are three dimensional constructions, and it is understood that voltage may be applied across a three dimensional planar membrane, across a wire, or simply at points at an edge or region on the pixel. Additionally, voltage may be applied to a point or points on the pixel to create the profiles discussed and suggested herein. Thus use of the term “line” herein with respect to voltage application is not intended to be in any way limiting.

The voltage ramp 604 of the present design may increase linearly with pixel height 607 from V1 at 602 to V2 at 603. This applied continuous voltage ramp 604 typically causes electrons shown at point 605 to move towards charge accumulation region 606, wherein the charge may then be measured or read out.

The present design may vary the slope of voltage ramp 604 by regulating the amount of difference in voltage potentials between the two sides of each pixel in the array. Increasing the difference in voltage potentials between V1 and V2 will increase the slope of the line representing the voltage ramp 604. Similarly, decreasing the difference in voltage potentials between V1 and V2 decrease the slope of the line representing voltage ramp 604. Regulating the difference between these two voltage potentials can result in a wide range of voltage ramps 604 slopes and thus regulate the rate that the electrons move from one side of each pixel to the other side of the pixel.

Further, while a linear voltage progression is shown, other progressions may be formed by alternating the voltages applied to the surface of the pixel. And while regions 630 and 640 may provide antiblooming features and drain features, these regions are optional in FIG. 6 and FIG. 5 and all embodiments of the current design.

The present design may alternatively use multiple gates with a voltage profile represented by discrete voltage potentials, each voltage potential differing by a small value as compared to an adjacent gate. The stepped voltages approximate a linear ramp but result in constant potential regions with vanishing drift field in the linear sensor that are more sensitive to device variability such as charge trapping and voltage offsets from process-induced gate-dependent fixed charges. The present design for high-speed inspection and metrology applications uses a linear continuous voltage ramp 604 best suited to reduce image lag associated with linear sensors. Use of back side illumination can provide P, n−, and oxide layers enabling voltage profiles such as those shown here and can enable the relatively rapid transition of charge from the pixel to the charge accumulation regions as shown herein. The decrease in image lag results from the back side illumination and constructions illustrated herein.

The inspection system design previously outlined uses a back-thinned linear sensor. Device thinning is generally known in the inspection and sensor art, generally comprising removing material from the back side of a substrate using chemical or mechanical methods. Back thinning can enhance light sensitivity overall and can provide greatly improved sensitivity for UV light energy.

The design presented herein and the specific aspects illustrated are meant not to be limiting, but may include alternate components while still incorporating the teachings and benefits of the invention, namely the moving of electron charge within a plurality of linear pixels in an array forming a back-side illuminated linear sensor using voltage profiles generated using one continuous resistive gate or a plurality of highly conducting or resistive gates. While the invention has thus been described in connection with specific embodiments thereof, it will be understood that the invention is capable of further modifications. This application is intended to cover any variations, uses or adaptations of the invention following, in general, the principles of the invention, and including such departures from the present disclosure as come within known and customary practice within the art to which the invention pertains.

1. A specimen inspection device, comprising:
optics configured to focus a beam of radiation into a focused beam at an oblique incidence angle to a focused line on a surface of a specimen; and
a back side illuminated linear sensor configured to receive light energy via the focused line, the back side illuminated linear sensor comprising:
an array of linearly aligned pixels comprising:
a polysilicon gate layer configured to receive light energy from a back side of the pixel, wherein said polysilicon gate layer is configured to have at least one relatively low voltage applied thereto and at least one relatively high voltage applied thereto, wherein charge advances from a low voltage region of said polysilicon gate layer to a higher voltage region of said polysilicon gate layer.

2. The specimen inspection device of claim 1, wherein the polysilicon layer comprises a single continuous polysilicon gate covering an entire exposure region of the pixel, and the specimen inspection device is configured to provide a relatively continuous voltage ramp over the single continuous polysilicon gate.

3. The specimen inspection device of claim 1, wherein the polysilicon gate layer comprises a voltage profile formed by a plurality of polysilicon gates covering an entire exposure region of the pixel.

4. The specimen inspection device of claim 2, wherein the specimen inspection device is configured to apply voltages to the polysilicon layer, said voltages forming a voltage profile, and wherein the voltage profile comprises a continuous voltage ramp from a first side of one pixel to a second side of the pixel.

5. The specimen inspection device of claim 3, wherein the specimen inspection device is configured to apply voltages to the polysilicon layer, said voltages forming a voltage profile, and wherein the voltage profile comprises a plurality of discrete voltage potentials continually increasing from a first side of one pixel to a second side of the pixel.

6. The specimen inspection device of claim 1, further comprising an overflow gate, wherein voltage of the overflow gate is used to set well capacity of the pixel in an adjustable manner from zero capacity to a maximal capacity.

7.-17. (canceled)

18. A back side illuminated linear sensor configured for use in an inspection device, the back side illuminated linear sensor comprising an imaging region formed by a linearly aligned plurality of pixels, wherein each pixel comprises:
a polysilicon gate layer;
an oxide layer formed adjacent to the polysilicon gate layer;
a n-type material layer adjacent to said oxide layer; and
a p-type material formed adjacent to said n-type layer;
wherein energy is received from a specimen first through said p-type material and subsequently to said n-type layer, and further wherein charge progresses through said n-type layer from a first voltage region to a more positive voltage region of the pixel

19. The back side illuminated linear sensor of claim 18, wherein said polysilicon layer comprises a region wherein a low voltage is applied and a further region where a high voltage is applied, and further comprises an accumulation region employed to collect charge progressing through the polysilicon layer.

20. The back side illuminated linear sensor of claim 18, wherein said sensor receives ultraviolet light reflected from a specimen.

21. A back side illuminated linear sensor configured for use in an inspection device, the back side illuminated linear sensor comprising:
an array of linearly aligned pixels comprising:
a polysilicon gate layer configured to receive light energy from a back side of the pixel, wherein said polysilicon gate layer is configured to have at least one relatively low voltage applied thereto and at least one relatively high voltage applied thereto, wherein charge advances from a low voltage region of said polysilicon gate layer to a higher voltage region of said polysilicon gate layer.

22. The sensor of claim 21, wherein the polysilicon layer comprises a single continuous polysilicon gate covering an entire exposure region of the pixel, and the sensor is configured to provide a relatively continuous voltage ramp over the single continuous polysilicon gate.

23. The sensor of claim 21, wherein the polysilicon gate layer is configured to operate in accordance with a voltage profile formed by a plurality of polysilicon gates covering an entire exposure region of the pixel.

24. The sensor of claim 22, wherein the sensor is configured to apply voltages to the polysilicon layer, and said voltages form a voltage profile, and wherein the voltage profile comprises a continuous voltage ramp from a first side of one pixel to a second side of the pixel.

25. The sensor of claim 23, wherein the sensor is configured to apply voltages to the polysilicon layer, and said voltages form a voltage profile, and wherein the voltage profile comprises a plurality of discrete voltage potentials continually increasing from a first side of one pixel to a second side of the pixel.

26. The sensor of claim 21, further comprising an overflow gate, wherein voltage of the overflow gate is used to set well capacity of the pixel in an adjustable manner from zero capacity to a maximal capacity.

27. The sensor of claim 22, wherein at least one pixel in said sensor comprises an anti-blooming gate region configured to collect electrons that may saturate specific pixels receiving relatively bright illumination.

28. The sensor of claim 23, wherein at least one pixel in the sensor is back thinned and a plurality of pixels in the sensor are linearly aligned and are configured to perform metrology tasks.

29. The sensor of claim 21, wherein the pixels in the sensor are long aspect ratio pixels able to achieve relatively high speed inspection of the specimen.

30. A sensor comprising:
an array of linearly aligned pixels comprising:
a polysilicon gate layer configured to receive light energy from a back side of the pixel, said polysilicon gate layer comprising:
a low voltage region; and
a higher voltage region;
wherein said polysilicon gate layer is configured to have at least one relatively low voltage applied thereto and at least one relatively high voltage applied thereto, and as a result of relatively low voltage and relatively high voltage application to the polysilicon gate layer, a charge advances from the low voltage region of said polysilicon gate layer to the higher voltage region of said polysilicon gate layer.

31. The sensor of claim 30, wherein the polysilicon layer comprises a single continuous polysilicon gate covering an entire exposure region of the pixel, and the sensor is configured to provide a relatively continuous voltage ramp over the single continuous polysilicon gate.

32. The sensor of claim 30, wherein the polysilicon gate layer is configured to operate according to a voltage profile formed by a plurality of polysilicon gates covering an entire exposure region of the pixel.

33. The sensor of claim 31, wherein the sensor is configured to apply voltages to the polysilicon layer, the voltages forming a voltage profile, and wherein the voltage profile comprises a continuous voltage ramp from a first side of one pixel to a second side of the pixel.

34. The sensor of claim 32, wherein the sensor is configured to apply voltages to the polysilicon layer, the voltages forming a voltage profile, and wherein the voltage profile comprises a plurality of discrete voltage potentials continually increasing from a first side of one pixel to a second side of the pixel.

35. The sensor of claim 30, further comprising an overflow gate, wherein voltage of the overflow gate is used to set well capacity of the pixel in an adjustable manner from zero capacity to a maximal capacity.

36. The sensor of claim 31, wherein at least one pixel in said sensor comprises an anti-blooming gate region configured to collect electrons that may saturate specific pixels receiving relatively bright illumination.

37. The sensor of claim 32, wherein at least one pixel in the sensor is back thinned and a plurality of pixels in the sensor are linearly aligned and are configured to perform metrology tasks.

38. The sensor of claim 30, wherein the pixels in the sensor are long aspect ratio pixels able to achieve relatively high speed inspection of the specimen.
